(19) United States
(12) Patent Application Publication
(10) Pub. No.: US 2025/0157819 A1
(43) Pub. Date: May 15, 2025

(54) METHOD FOR PROCESSING A SUBSTRATE

(71) Applicant: ASM IP Holding B.V., Almere (NL)

(72) Inventors: SeungHyun Lee, Seoul (KR); Hyunchul Kim, Hwaseong-si (KR); SeungWoo Choi, Hwaseong-si (KR); YeaHyun Gu, Hwaseong-si (KR)

(21) Appl. No.: 19/018,312

(22) Filed: Jan. 13, 2025

Related U.S. Application Data
(62) Division of application No. 17/233,382, filed on Apr. 16, 2021, now Pat. No. 12,243,742.
(60) Provisional application No. 63/013,517, filed on Apr. 21, 2020.

(51) Int. Cl. H01L 21/033; H01L 21/02

(52) U.S. Cl. CPC H01L 21/0332; H01L 21/02164; H01L 21/02274; H01L 21/0228

(57) ABSTRACT

Provided is a method to adjust a film stress. In one embodiment, a first film is formed on the substrate by supplying a first reactant and a second reactant sequentially and alternately in a first step, and the first film is converted into a second film by supplying a third reactant to the first film in a second step. The film stress of the second film is adjusted by controlling the ratio of the first step and the second step.

### CROSS-REFERENCE TO RELATED APPLICATIONS

This application is a divisional of, and claims priority to, U.S. patent application Ser. No. 17/233,382 filed Apr. 16, 2021 titled METHOD FOR PROCESSING A SUBSTRATE; which claims the benefit of and priority to U.S. Provisional Application No. 63/013,517, filed on Apr. 21, 2020 in the United States Patent and Trademark Office, the disclosures of which are incorporated herein in their entirety by reference.

### BACKGROUND

### 1. Technical Field

The disclosure provides a method for processing a substrate, more specifically a method for adjusting a stress of a film formed on the substrate.

### 2. Description of the Related Art

A substrate and a film formed on it may undergo a thermal treatment in a high temperature process creating stress. This may cause a deformation of the substrate such as warpage or crack, or film peeling-off or deterioration of device properties. FIG. 1 shows how a stress of a film may cause a peeling-off of a film or break or deformation of a substrate.

### SUMMARY

The present disclosure provides a method for processing a substrate. More specifically this disclosure provides a method for adjusting a stress of a film.

According to one embodiment, a first film may be formed on the substrate by supplying a first reactant and a second reactant sequentially and alternately in a first step. The first film may be converted into a second film by supplying a third reactant in a second step. The second reactant may be activated. The third reactant may be activated and reactive to the first film. The stress of the second film may be adjusted by controlling the cycle ratio of the first step and the second step.

According to another embodiment, a first film may be formed on the substrate with a pattern as a hardmask by supplying a first reactant and a second reactant sequentially and alternately in a first step. The first film may be converted into a second film by supplying a third reactant in a second step. The second reactant may be activated. The third reactant may be activated and reactive to the first film. The wet etch rate of the hardmask formed at 50° C. may be almost the same as that of silicon oxide hardmask formed at 300° C. or above.

According to another embodiment, a first film may be formed on the backside of a substrate by supplying a first reactant and a second reactant sequentially and alternately in a first step, and may be converted into a second film by supplying a third reactant in a second step. The second reactant may be activated. The third reactant may be activated and reactive to the first film. A third film may be formed on the front side of the substrate at high temperature. The second film may be etched out after processing the substrate.

According to another embodiment, a substrate having a gap to be filled is provided and the gap may be filled with a first film. A second film may be formed on the first film by supplying a first reactant and a second reactant sequentially and alternately in a first step, and may be converted into a third film by supplying a third reactant in a second step. The second reactant may be activated. The third reactant is activated and reactive to the second film.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view of a stress-induced peeling-off of a film and deformation of a substrate.

FIG. 2 is a view of a substrate processing flow according to one embodiment.

FIG. 3 is a schematic view of a process flow according to one embodiment.

FIG. 4 is a schematic view of definition of duty ratio.

FIG. 5 is a schematic view of process flow according to another embodiment.

FIG. 6 is a graph showing SiO₂ film stress in accordance with a cycle ratio of step 1 and step 2.

FIG. 7 is a view of SiO₂ film composition.

FIG. 8 is a view of substrate processing flow according to another embodiment.

FIGS. 9A and 9B are schematic views of process according to another embodiment.

FIG. 10 is a view of substrate processing flow according to another embodiment.

FIG. 11 is a graph showing wet etch rate of SiO₂ film at various conditions.

FIGS. 12A and 12B are schematic views of process according to another embodiment.

FIG. 13 is a view of substrate processing flow according to another embodiment.

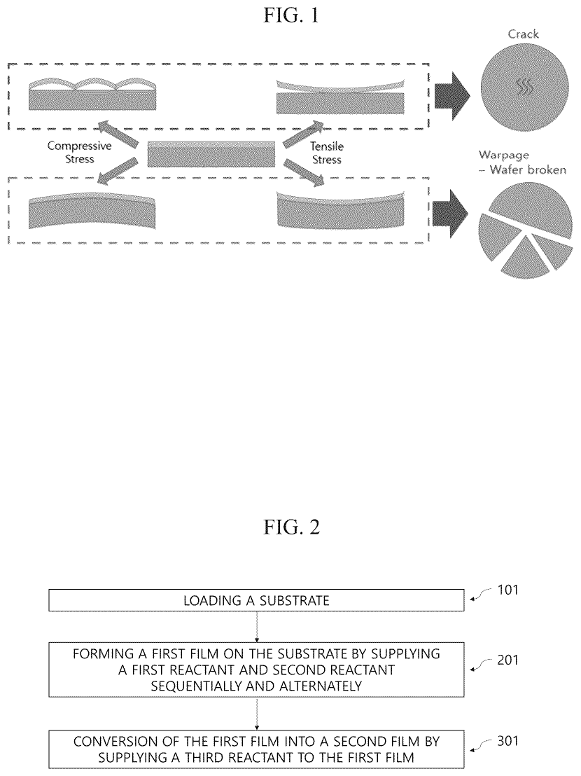

### DETAILED DESCRIPTION

A substrate processing method according to this disclosure provides methods to adjust a stress of a film and prevent and/or suppress a substrate deformation or film peeling-off occurred due to the stress of a film or a substrate.

FIG. 2 is a process flow according to one embodiment and the details of FIG. 2 is described as follows.
Loading a substrate (101): A substrate may be loaded onto a substrate support in the reaction space. The substrate support supports the substrate and provides a heat energy to the substrate to keep the substrate temperature at designated temperature.
Forming a first film (201): A first film may be formed on the substrate by supplying a first reactant and a second reactant alternately and sequentially to the substrate. The first reactant may be a precursor containing a Si element and the second reactant may be activated by radio frequency power. The second reactant may not chemically react with the first reactant. For example, the first reactant may be an aminosilane precursor. The second reactant may be inactive gas such as Ar or He or a combination thereof. In this step, the first reactant may be dissociated and broken by plasma, and adsorbed onto the substrate. Since there may be no chemical reaction between the first reactant and the second reactant, the film adsorbed onto the substrate may comprise fragments of the dissociated or broken first reactant molecules, e.g. silicon (Si), carbon (C), nitrogen (N), chlorine (Cl), iodine (I), alkyl group ligand (e.g. CₙH₂ₙ₊₁) and hydrogen (H) fragments and/or the mixture thereof. A first layer of the first film may be chemisorbed to the substrate. The second layer may be deposited over the first film and may comprise a stack of those fragments. The first film may be densified by the activated second gas. Also, the activated second gas may contribute to the dissociation of the first gas. This first step may be repeated “M” times.
Conversion of the first film into a second film (301): A third reactant may be supplied to the first film formed on the substrate. The third reactant may be activated by radio frequency power and chemically reacts to the first film. The third reactant may be oxygen-containing gas, more preferably the third reactant may be oxygen. In this step, the first film may be converted into a second film. Since the activated third reactant chemically reacts to the first film, the first film may be converted into the second film. The second film, for example, may be SiO₂ film. This second step may be repeated “N” times.

In FIG. 2, a cycle ratio of first step 201 to second step 301 may be larger than 5, preferably larger than 20 or more preferably larger than 50. For example, the first step 201 may be repeated 50 times and the second step 301 may be repeated one time. Further, the first step 201 and the second step 301 may be repeated “X” times, at least one time as a group cycle or super-cycle to more facilitate the conversion of the first film into the second film as the first film thickness increases.

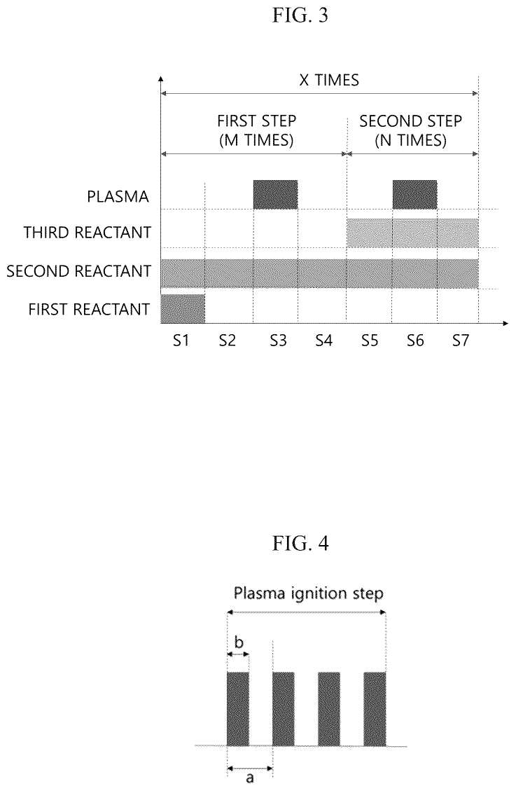

FIG. 3 is a schematic view of the process flow of FIG. 2. A first step and a second step of FIG. 3 correspond to a first step 201, a second step 301 of FIG. 2 respectively. In first step of FIG. 3, a first layer may be formed by supplying a first reactant and a second reactant sequentially and alternately. A second reactant may be activated by a radio frequency power, for example.

In another embodiment a second reactant may be supplied continuously as shown in FIG. 3. In FIG. 3, the first step may be repeated “M” times, at least one time, followed by the second step. In second step of FIG. 3, a third reactant may be supplied and activated by plasma and the second step may be repeated “N” times, at least one time. The cycle ratio of the first step and the second step, that is M/N, may be larger than 5, preferably larger than 20 or more preferably larger than 50. The activated third reactant may convert the first film into the second film. For example, the first reactant may be a Si-containing precursor, the second reactant may be Ar and the third reactant may be oxygen. The Si-containing precursor as the first reactant may be at least one of DIPAS, SiH₃N(iPr)₂; TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄-; HCD, Si₂Cl₆; 3DMAS, SiH(N(Me)₂)₃; BEMAS, Si H₂[N(Et)(Me)]₂; AHEAD, Si₂(NHEt)₆; TEAS, Si(NHEt)₄; Si₃H₈; DCS, SiH₂Cl₂; SiHI₃; SiH₂I₂ or mixture thereof. The oxygen gas as the third reactant may be at least one of O₂, O₃, CO₂, H₂O, NO₂ and N₂O or mixture thereof.

The first film may be a stack of fragments of Si precursor molecules densified by plasma and may be converted into SiO₂ as the second film by oxygen plasma. In other words, the step 1 may be a source coating step and the step 2 may be an oxygen treatment step. In FIG. 3, a plasma condition of step 2 may vary. For example, a radio frequency power may be provided in pulse with a certain duty ratio to reduce a damage to the substrate or sublayer.

When the radio frequency power is provided in pulse, the ratio of the actual radio frequency power supply time b to the unit cycle time a of radio frequency pulsing, that is b/a, is defined as a duty ratio as shown in FIG. 4. In another embodiment according to this inventive concept, the radio frequency power may be provided in pulse with a range of duty ratio of 10% to 75%.

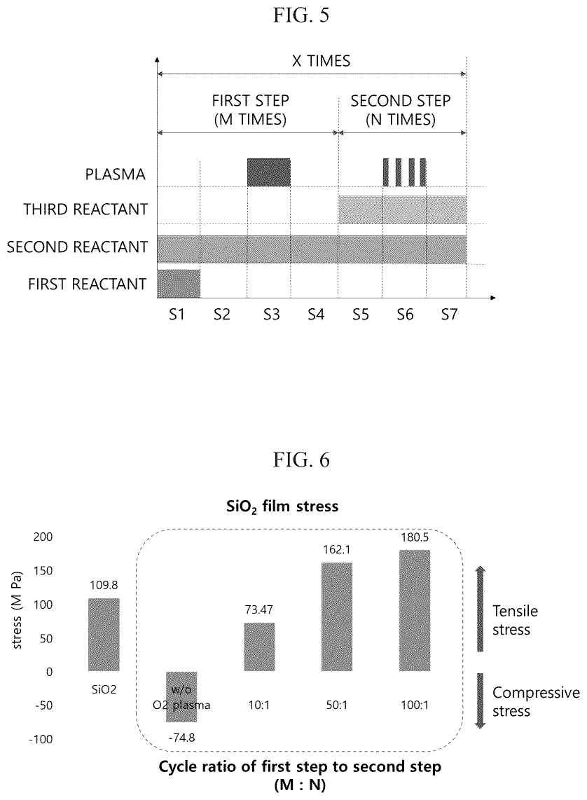

FIG. 5 is another embodiment according to the inventive concept. In first step a plasma may be supplied in continuous mode, but in second step a plasma may be supplied in pulse mode with certain duty ratio. But supplying a plasma in pulse is not limited thereto. In another embodiment, a plasma may be supplied in pulse to at least one of the first step and the second step.

Table 1 is an experimental condition of one embodiment according to FIG. 3 in which plasma may be supplied in continuous mode in which plasma may not be supplied in pulse.

TABLE 1
an experimental condition of one embodiment

| Items | Conditions |
|---|---|
| Process temperature (° C.) | room temperature to 150° C. (preferably 50 to 150° C.) |
| Process pressure (Torr) | 1.0 to 5.0 Torr (preferably 2.0 to 3.0 Torr) |
| Si precursor | DIPAS (diisopropylaminosilane) |
| Reactant | O₂ |
| Purge gas | Ar |

First step @ forming a first film

| | | |
|---|---|---|
| Process | Source feed(S1) | 0.05 to 2.0 sec. (preferably 0.1 to 1.0 sec.) |
| time (sec) | Source purge(S2) | 0.05 to 2.0 sec. (preferably 0.1 to 1.0 sec.) |
| | Plasma-on(S3) | 0.05 to 2.0 sec. (preferably 0.1 to 1.0 sec.) |
| | Purge(S4) | 0.05 to 2.0 sec (preferably 0.1 to 1.0 sec) |
| | S1~S4 cycle | 50 to 200 cycles (preferably 100 to 150 cycle) |
| Gas flow | Source carrier Ar | 100 to 10,000 sccm (preferably 600 to 1,200 sccm) |
| rate (sccm) | Purge Ar | 1,000 to 10,000 sccm (preferably 3,000 to 6,000 sccm) |
| Plasma | RF power(W) | 100 to 1,000 W (preferably 200 to 400 W) |
| condition | RF frequency | 13 to 100 MHz (preferably 27 to 60 MHz) |

Second step@ conversion of the first film into the second film

| | | |
|---|---|---|
| Process | Pre purge(S5) | 0.05 to 5.0 sec(preferably 0.5 to 5.0 sec) |
| time (sec) | Plasma-on(S6) | 0.05 to 3.0 sec(preferably 0.1 to 2.0 sec) |
| | Purge(S7) | 0.05 to 2.0 sec(preferably 0.1 to 1.0 sec) |
| | S5~S7 cycle | 1 to 10 cycle(preferably 1 to 5 cycle) |
| Gas flow | Reactant(O2) | 50 to 1000 sccm(preferably 200 to 500 sccm) |
| rate (sccm) | Purge Ar | 1,000 to 10,000 sccm(preferably 3,000 to 6,000 sccm) |
| Plasma | RF power(W) | 100 to 1,000 W(preferably 200 to 500 W) |
| condition | RF frequency | 13 to 100 MHz(preferably 27 to 60 MHz) |

FIG. 6 shows a film stress in accordance with the cycle ratio of a first step and a second step. In FIG. 6, a SiO₂ film formed at room temperature by normal process in which Si-containing precursor and oxygen plasma are provided alternately and sequentially to form SiO₂ film may have a tensile stress of 109.8 MPa, but the SiO₂ film stress according to this inventive concept may vary in accordance with the cycle ratio of the first step and the second step.

In first step a Si-containing precursor as a first reactant and Ar plasma as a second reactant may be alternately and sequentially provided to the substrate to form a first film consisted of fragments of elements and/ligands of dissociated Si precursor.

In second step, an oxygen plasma as a third reactant may be provided to the first film to convert the first film into SiO₂ film as a second film. In one embodiment, a cycle ratio of the first step to the second step may be 50. For example, the first step may be 50 cycles and the second step may be one cycle. In another embodiment, a cycle ratio of the first step to the second step may be 100. For example, the first step may be 100 cycles and the second step may be one cycle.

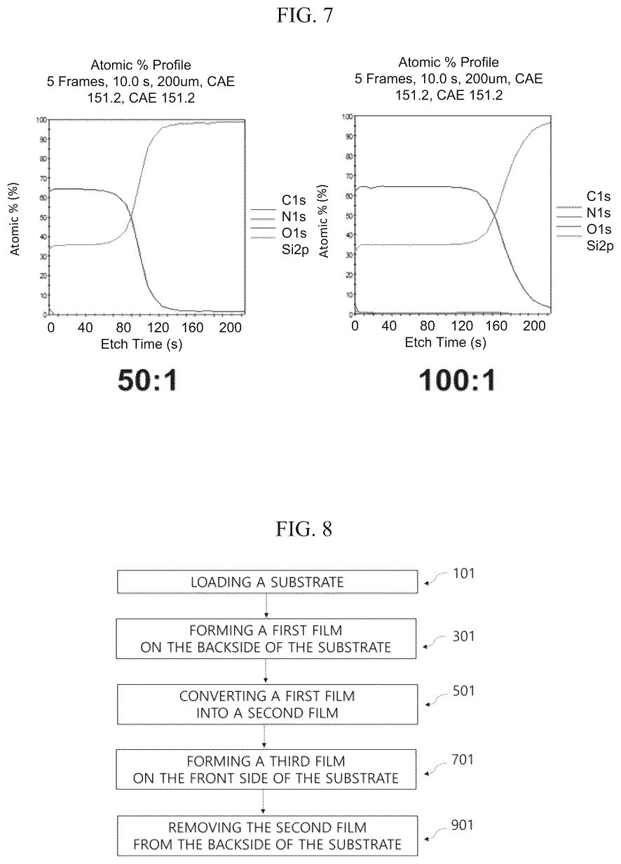

FIG. 7 shows a film composition after carrying out the first step and the second step. As shown in FIG. 7, SiO₂ films formed under the cycle ratio of 50:1 and 100:1 conditions of FIG. 6, for example, have stoichiometric SiO₂ film compositions without other elements coming from fragments of nitrogen, carbon and hydrogen or mixture thereof. This means the first film may be substantially converted into the second film by oxygen plasma as a third reactant.

As shown in FIG. 6, a film stress of the first film has a compressive stress of −74.8MPa, but as the oxygen plasma is provided and the first film is converted into the second film, a film stress is turned into a tensile stress. Also the higher the cycle ratio of the step 1 to the step 2 is, the higher the tensile stress of SiO₂ film is. That is, SiO₂ film stress may be properly adjusted by controlling the cycle ratio of the first step and the second step. So, the optimal process condition or the cycle ratio may be set to prevent a substrate deformation and film peeling-off, e.g. warpage, crack, etc. So a film with targeted stress may be formed by controlling the cycle ratio.

In another embodiment this process may be carried out to introduce a stress control film. For instance, if a substrate is processed at high temperature in a reactor, undergoing a compressive or a tensile stress, then the substrate may be deformed or broken, or film peeling-off or crack in it may occur. In this case, a stress control film may be introduced to the backside of the substrate to offset a compressive or a tensile stress of the substrate. The stress control film may be a film with a compressive stress or a tensile stress formed by a method in accordance with aforementioned FIG. 2 and FIG. 3 before processing a substrate That is, a stress of the stress control film may offset a stress of the substrate by adjusting the cycle ratio of the source coating step and the plasma treatment step. So the stress control film may suppress a substrate deformation and cracks in a film on the substrate during processing a substrate at high temperature. FIG. 8 shows a process flow introducing a stress control film.

In FIG. 8, a first film may be formed on the backside of the substrate by supplying a first reactant and a second reactant in a first step. Then the first film may be converted into a second film by supplying a third reactant in a second step. A stress of the second film may be adjusted by controlling the cycle ratio of the first step and the second step, and the second film may act as a stress control film. The process sequence is described in FIG. 2 and FIG. 3 in more detail, so the detailed description of it is omitted herein. Then a third film may be formed on the front side of the substrate. After the process is completed, the stress control film, that is, the second film may be removed by a fluorine-containing etchant such as CF₄. By carrying out this process, deformation or break of the substrate and cracks or damages in the third film may be suppressed.

The process of FIG. 8 may be performed ex-situ. For example, this process may be carried out in a chamber with a plurality of reactor in it. For example, the substrate may be processed by being transferred sequentially from one reactor to another to carry out each step of FIG. 8.

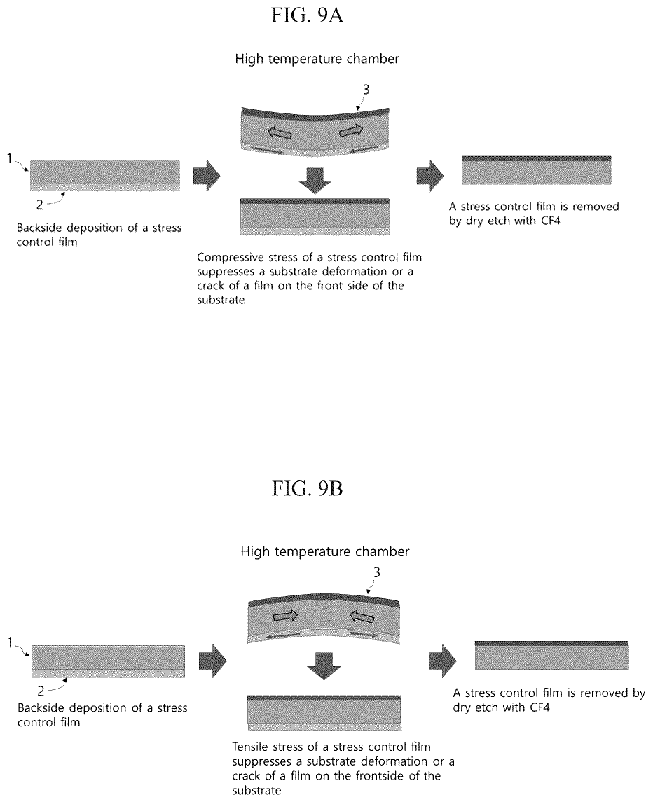

FIG. 9 shows embodiments of FIG. 8. In FIG. 9A, a second film or a stress control film 2 may be formed on the backside of the substrate 1 at low temperature, e.g. room temperature. Then a targeted third film 3 may be formed on the front side of the substrate 1 at high temperature. A stress of the substrate may be offset by introducing a stress control film with a compressive stress or a tensile stress to the backside of the substrate 1.

In FIG. 9A a tensile stress of the substrate may be offset by forming a stress control film 2 with compressive stress on the backside of the substrate 1, so deformation or break of the substrate or cracks in a third film 3 on the substrate may be suppressed.

In FIG. 9B a compressive stress of the substrate may be offset by forming a stress control film 2 with tensile stress on the backside of the substrate 1, so deformation or break of the substrate or cracks in a third film 3 on the substrate may be suppressed.

Controlling a film stress by converting one film into another one at low temperature provides another technical benefit. A SiO₂ hardmask may be used in patterning process of semiconductor device fabrication. But as the device shrinkages, a film thickness on the device becomes thinner and a thermal budget becomes a serious problem since it causes a sublayer damage, abnormal migration of electrons across the structures of the device and malfunction of the device. So a SiO₂ hardmask process at low temperature may be required with the same film properties as the one formed at the existing high temperature process. So the inventive concept according to this invention may provide a solution to it.

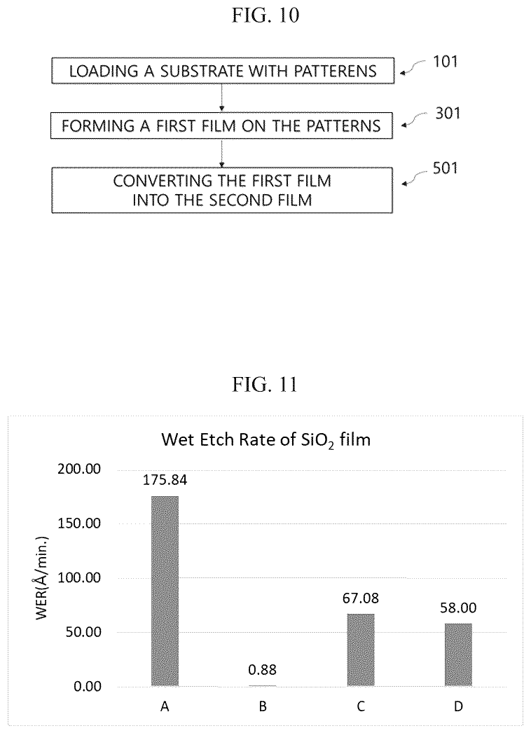

FIG. 10 shows a process flow for forming a hardmask on patterns of the substrate according to another embodiment.

In the first step 101 of FIG. 10, a substrate with pattern structure may be loaded to a substrate support. In the second step 301 of FIG. 10, a first film may be formed on the pattern of the substrate. The first film may be formed in accordance with the aforementioned method in FIG. 2 and FIG. 3, so detailed description will be omitted herein. After the second step 301, the first film may be converted into a second film in the third step 501. The conversion of the first film into the second film may be carried out in accordance with the aforementioned method in FIG. 2 and FIG. 3, so detailed description will be omitted herein.

FIG. 11 shows a wet etch ratio (WER) of SiO₂ film formed in accordance with FIG. 10 and the existing method. The wet etch rate is carried out in hydrofluoric acid (HF) diluted in the ratio of 100:1 in deionized water (DIW).

In FIG. 11 details of each process condition are described as below.
A: SiO₂ film formed by normal PEALD method at 50° C. in which DIPAS (diisopropylaminosilane) precursor and oxygen plasma may be alternately and sequentially provided.
B: Precursor deposition. Si-containing film may be formed at 50° C. by supplying DIPAS silicon precursor and Ar plasma alternately and sequentially.
C: SiO₂ film formed at 50° C. by carrying out 50 cycles of alternate and sequential supply of DIPAS precursor and Ar plasma and one cycle of oxygen plasma to convert into SiO₂ film.
D: SiO₂ film for hardmask application formed at 300° C. by normal PEALD method in which DIPAS precursor and oxygen plasma may be alternately and sequentially provided.

As shown in A of FIG. 11, SiO₂ film formed at 50° C. by normal PEALD method has high wet etch rate of 175.84 Å/min, in other words, low wet etch resistance. But in B condition a Si-containing film formed at 50° C. by supplying DIPAS precursor and Ar plasma has very low WER, in other words, high wet etch resistance. But as shown in C, oxygen treatment and a resultant conversion of Si-containing film into SiO₂ film at 50° C. increases the WER closer to that of SiO₂ film formed at 300° C. shown in condition D. In another embodiment, the WER of SiO₂ film formed at 50° C. may be almost the same as that of SiO₂ film formed at 300° C. or above by further controlling the cycle ratio of the first step and the second step. In other words, by adjusting the cycle ratio of the precursor deposition step and the plasma treatment step, film properties that may be achieved at high temperature, e.g. 300° C. or above may be achieved at low temperature, reducing a thermal budget to a device. So the inventive concept of this invention may provide a solution to the requirement for low temperature process. FIG. 11 also shows that films with different wet etch rates may be realized at low temperature by adjusting the cycle ratio of the precursor deposition step and the plasma treatment step, and this may make various applications available.

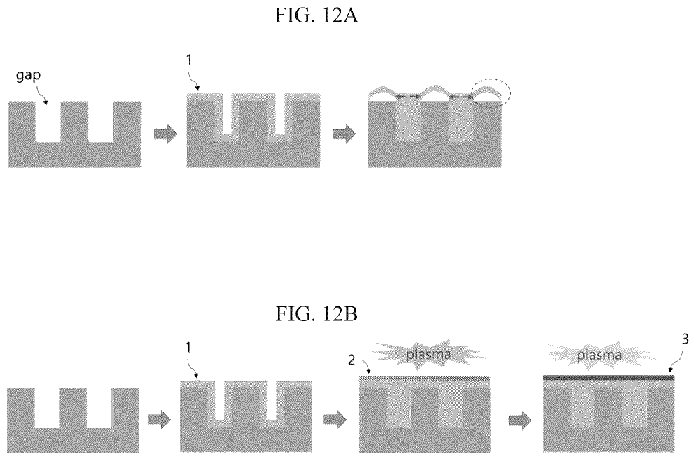

Controlling a film stress by converting one film into another one may provide another technical benefit in gap fill process. In FIG. 12, a film 1 covering a top surface may be peeled off due to film stress, e.g. tensile stress as shown FIG. 12A. But introducing a stress control film to the top surface of the film may suppress the film peeling-off as shown FIG. 12B.

In FIG. 12B, a gap is filled with a first film 1 and a second film or a stress control film 2 may be formed by supplying a first reactant and a second reactant activated by plasma in a first step, and the second film may be converted into a third film 3 in a second step. A stress of the third film 3 may be adjusted by controlling the cycle ratio of the first step and the second cycle. The details of the process is aforementioned in FIG. 2 and FIG. 3, so detailed description of it will be omitted herein.

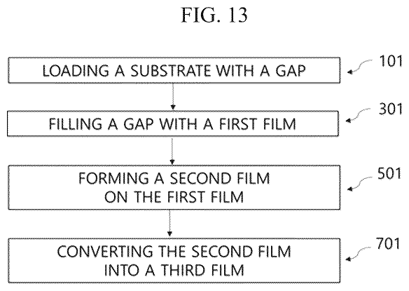

FIG. 13 shows a process flow of FIG. 12 in which a substrate with gap structure may be loaded at step 101, followed by filling the gap with a first film at step 301. A second film may be formed on the first film at step 501, followed by being converted into a third film at step 701.

What is claimed is:

1. A method for adjusting a film stress comprising:
loading a substrate onto a substrate support of a reactor;
forming a first film on the backside of the substrate by supplying a first reactant and a second reactant sequentially and alternately in a first step;
converting the first film into a second film by supplying a third reactant to the first film in a second step;
forming a third film on the front side of the substrate;
removing the second film from the backside of the substrate, wherein the cycle ratio of the first step to the second step is larger than 5 to adjust the stress of the second film.

2. The method according to claim 1, wherein a stress of the second film offsets a stress of the substrate.

3. The method according to claim 1, wherein the third film is formed at 300° C. or higher.

4. The method according to claim 1, wherein the substrate is processed by being transferred sequentially from one reactor to another reactor in a system with a plurality of reactors.

5. The method according to claim 1, wherein the second reactant is activated by a radio frequency power.

6. The method according to claim 1, wherein the third reactant is activated by a radio frequency power and chemically reacts to the first film.

7. The method according to claim 1, wherein the first reactant is silicon-containing gas.

8. The method according to claim 1, wherein the second reactant is at least one of Ar and He, or mixture thereof.

9. The method according to claim 1, wherein the third reactant is an oxygen-comprising gas.

10. The method according to claim 1, wherein the second film is silicon oxide.

11. The method according to claim 1, wherein the first step is repeated at least one time and the second step is repeated at least one time; and
the first step and the second step are repeated sequentially at least one time as a group cycle.

12. A method for adjusting a film stress comprising:
loading a substrate onto a substrate support;
forming a first film on the substrate;
forming a second film on the first film comprising:
supplying a first reactant and a second reactant alternately and sequentially in a first step.
converting the second film into a third film by supplying a third reactant to the second film in a second step,
wherein the cycle ratio of the first step to the second step is larger than 5 to adjust the stress of the second film.

13. The method according to claim 12, wherein the second reactant is activated by a radio frequency power.

14. The method according to claim 12, wherein the third reactant is activated by a radio frequency power and chemically reacts to the second film.

15. The method according to claim 12, wherein the stress of the third film offsets a stress of the first film.

16. The method according to claim 12, wherein the first reactant is silicon-containing gas.

17. The method according to claim 12, the second reactant is at least one of Ar and He, or mixture thereof.

18. The method according to claim 12, the third reactant is oxygen-containing gas.

19. The method according to claim 12, wherein the third film is silicon oxide.

20. The method according to claim 12, wherein the first step is repeated at least one time and the second step is repeated at least one time; and
the first step and the second step are repeated sequentially at least one time as a group cycle.

21. The method according to claim 12, wherein the substrate has a gap to be filled; and the gap is filled with the first film.
